(19) United States
(12) Patent Application Publication
(10) Pub. No.: US 2025/0301808 A1
(43) Pub. Date: Sep. 25, 2025

(54) LIGHT DETECTING DEVICES WITH DOPED TRANSFER GATES AND SYSTEMS AND METHODS FOR THE SAME

(71) Applicant: SONY SEMICONDUCTOR SOLUTIONS CORPORATION, Kanagawa (JP)

(72) Inventors: SUNGIN HAN, New York, NY (US); Hongyi MI, New York, NY (US)

(73) Assignee: SONY SEMICONDUCTOR SOLUTIONS CORPORATION, Kanagawa (JP)

(21) Appl. No.: 18/610,026

(22) Filed: Mar. 19, 2024

(51) Int. Cl. H01L 27/146; G01J 1/44

(52) U.S. Cl. CPC H10F 39/80373; G01J 1/44; H10F 39/014; G01J 2001/4473

(57) ABSTRACT

A light detecting device includes a photoelectric conversion region that is disposed in a semiconductor substrate and that converts light into electric charge. The light detecting device includes a plurality of transistors coupled to the photoelectric conversion region. At least one transistor of the plurality of transistors has a gate having a first conductivity type while remaining ones of the plurality of transistors have gates of a second conductivity type different than the first conductivity type.

### FIELD

Example embodiments relate to light detecting devices with doped transfer gates and systems and methods for the same.

### BACKGROUND

Light detecting devices, also called image sensors, are used to convert light into electrical signals that are processed form an image. A camera is a typical example of a consumer device that incorporates a light detecting device for the purpose of capturing images to be viewed by the user. In some applications, such as applications that involve head mounted displays (HMDs), images captured by a light detecting device may be used by other components within the overall system. For example, in an HMD that provides augmented reality (AR) and/or mixed reality (MR) images for a viewing by a user, a light detecting device may be incorporated into the HMD for the sake of tracking the user's eyes to improve the quality of the images displayed to the user's eyes by the HMD.

### SUMMARY

An illustrative embodiment is directed to a light detecting device including a photoelectric conversion region that is disposed in a semiconductor substrate and that converts light into electric charge, and a plurality of transistors coupled to the photoelectric conversion region. At least one transistor of the plurality of transistors comprises a gate having a first conductivity type while remaining ones of the plurality of transistors comprise a gate having a second conductivity type.

Another illustrative embodiment is directed to an electronic apparatus including a signal processing circuit and a light detecting device. The light detecting device includes a photoelectric conversion region that is disposed in a semiconductor substrate and that converts light into electric charge, and a plurality of transistors coupled to the photoelectric conversion region. At least one transistor of the plurality of transistors comprises a gate having a first conductivity type while remaining ones of the plurality of transistors comprise a gate having a second conductivity type.

Another illustrated embodiment is directed to a light detecting device including ga photoelectric conversion region that is disposed in a semiconductor substrate and that converts light into electric charge, and a plurality of transistors coupled to the photoelectric conversion region. At least one transistor of the plurality of transistors comprises a two-pronged vertical gate of a first conductivity type that extends into the semiconductor substrate.

### BRIEF DESCRIPTION OF THE FIGURES

FIG. 1 is a block diagram of a light detecting device according to at least one example embodiment.

FIG. 2 illustrates different examples of a pixel for inclusion in a light detecting device according to at least one example embodiment.

FIG. 3 illustrates an example plan view of a portion of a light detecting device and a method for manufacturing a light detecting device according to at least one example embodiment.

FIG. 4 illustrates band diagrams showing similarities between band diagrams for transfer gates having different conductivity types according to at least one example embodiment.

FIG. 5 illustrates reduced power consumption of a light detecting device according to at least one example embodiment.

FIG. 6 illustrates advantages of a dual vertical transfer gate structure according to at least one example embodiment.

FIG. 7 is a block diagram illustrating a possible configuration of an electronic apparatus that includes a light detecting device according to at least one example embodiment.

FIG. 8 illustrates a schematic view of a head mounted display (HMD) according to at least one example embodiment.

### DETAILED DESCRIPTION

Related art light detecting devices employ pixels that have gates of transfer transistors with gates formed from an n-type material, such as n-type polysilicon (n-poly). A typical off voltage for a n-type transfer gate is −1.2V, and thus requires a negative charge pump circuit to help reduce the dark current and maximize the electron capacity of the photoelectric conversion region of the pixel (herein, the term “transfer gate” should be understood to mean the gate of a transfer transistor that is controlled to transfer charge from a photoelectric conversion region to a another part of a pixel circuit, such as a floating diffusion). However, the negative charge pump circuit undesirably increases power consumption and chip size. Removing the negative charge pump and adjusting the transfer transistor off voltage to be 0V results unwanted defects such as increased dark current and increased white spots. It is possible to lower the potential of semiconductor material under and/or around an n-type transfer gate by implanting highly doped p-type material. However, the highly doped p-type material degrades charge transfer performance upon transferring charge from the photoelectric conversion region to a floating diffusion, thereby inducing an image lag problem.

Example embodiments of the present disclosure are directed to light detecting devices that achieve advantages compared to the related art, such as reduced power consumption, reduced chip size, and/or reduced unwanted capacitance compared to the related art by forming the transfer gate(s) from a p-type material, such as p-type polysilicon (p-poly), while maintaining the desired off voltage of 0V. These advantages are particularly useful for applications where power consumption and product size are significant considerations (e.g., HMD applications). Notably, a transfer gate formed of p-poly as described herein provides the same or nearly the same dark current performance as forming the transfer gate of n-poly with an off voltage of −1.2V. As described in more detail herein, concepts related to forming the transfer gate with a p-type material while keeping gates of other pixel transistors formed of n-type material may be combined with a dual vertical transfer gate structure. Stated another way, the gate of a transfer transistor within a pixel may be formed to have two (dual) prongs that penetrate the photoelectric conversion region to further improve charge transfer to a floating diffusion region while allowing for a lower on voltage that meets a given transfer barrier target.

Light detecting devices that have at least the above described advantages are described in more detail below with reference to the figures.

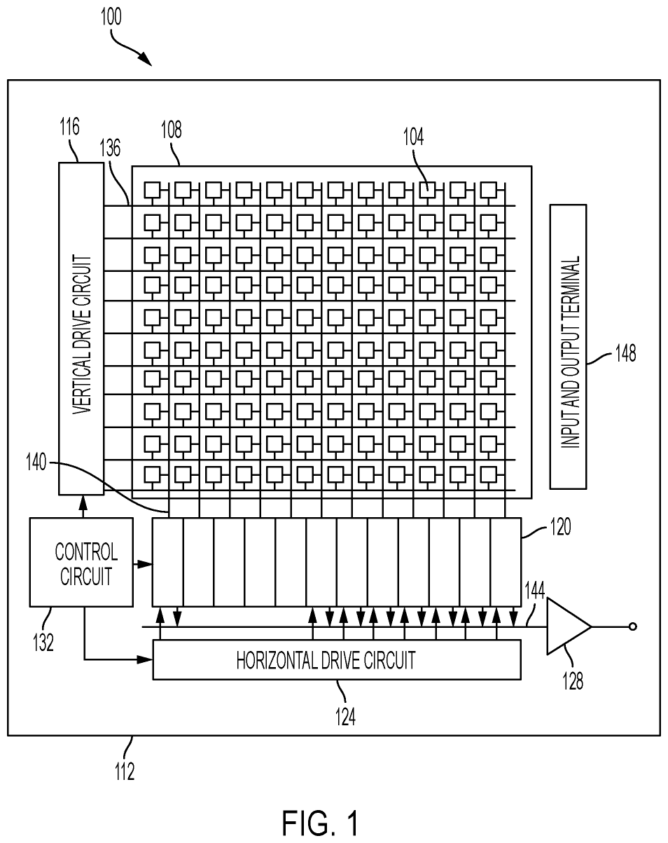

FIG. 1 is a diagram that depicts elements of an light detecting device 100 (also called an image sensor or an imaging device) in accordance with embodiments of the present disclosure. In general, the light detecting device 100 includes a plurality of pixels 104 disposed in an array 108. The light detecting device 100 may be a frontside or a backside illuminated sensor. The pixels 104 may be disposed within an array 108 having a plurality of rows and columns of pixels 104. Although not explicitly illustrated, each pixel 104 may have an associated microlens for focusing light toward one or more photoelectric conversion regions as well as one or more color filters that enable a pixel 104 to detect specific wavelengths of light (e.g., red, green, and blue wavelengths). Moreover, the pixels 104 may be formed on or in or on a sensor substrate 112, which may comprise a semiconductor material. In addition, one or more peripheral or other circuits can be formed in connection with the sensor substrate 112. Examples of such circuits include a vertical drive circuit 116, a column signal processing circuit 120, a horizontal drive circuit 124, an output circuit 128, and a control circuit 132. As described in greater detail elsewhere herein, each of the pixels 104 within an light detecting device 100 includes one or more photoelectric conversion regions or photoelectric conversion units that convert incident light into electric charge. In some examples, the photoelectric conversion region or photoelectric conversion unit is embodied by a photodiode (PD) disposed in a semiconductor substrate. In some examples, a pixel 104 includes a PD and further includes a photosensitive layer, such as an organic photoelectric conversion layer. In at least one embodiment, each pixel includes two or four or more sub-pixels with each sub-pixel including a photoelectric conversion region. As described in more detail below, a pixel 104 or a set of pixels 104 may comprise one or more pixel transistors, such as a transfer transistor, a reset transistor, an amplification transistor, and/or a selection transistor.

The vertical drive circuit 116 may, for example, be configured with a shift register, and may operate to select a pixel drive wiring 136 to supply pulses for driving pixels 104 through the selected drive wiring 136 in units of a row. The vertical drive circuit 116 may also selectively and sequentially scan elements of the array 108 in units of a row in a vertical direction, and supply the signals generated within the pixels 104 according to an amount of received light to the column signal processing circuit 120 through a vertical signal line 140.

The column signal processing circuit 120 can operate to perform signal processing, such as noise removal, on the signals output from the pixels 104. For example, the column signal processing circuit 120 can perform signal processing, such as correlated double sampling (CDS), to remove a specific fixed patterned noise of a selected pixel 104 and an analog to digital (A/D) conversion of the signal.

The horizontal drive circuit 124 can include a shift register. The horizontal drive circuit 124 may select each column signal processing circuit 120 in order by sequentially outputting horizontal scanning pulses, causing each column signal processing circuit 120 to output a pixel signal to a horizontal signal line 144.

The output circuit 128 may perform predetermined signal processing with respect to the signals sequentially supplied from each column signal processing circuit 120 through the horizontal signal line 144. For example, the output circuit 128 performs a buffering, black level adjustment, column variation correction, various digital signal processing, and other signal processing procedures. An input and output terminal 148 exchanges signals between the light detecting device 100 and external components or systems.

The control circuit 132 may receive data for instructing an input clock, an operation mode, and the like, and output data such as internal information related to the light detecting device 100. Accordingly, the control circuit 132 may generate a clock signal that provides a standard for operation of the vertical drive circuit 116, the column signal processing circuit 120, and the horizontal drive circuit 124, and control signals based on a vertical synchronization signal, a horizontal synchronization signal, and a master clock. The control circuit 132 outputs the generated clock signal in the control signals to the various other circuits and components.

Accordingly, at least portions of an light detecting device 100 in accordance with at least some embodiments of the present disclosure can be configured as a complementary metal oxide semiconductor (CMOS) image sensor of a column A/D type in which column signal processing is performed.

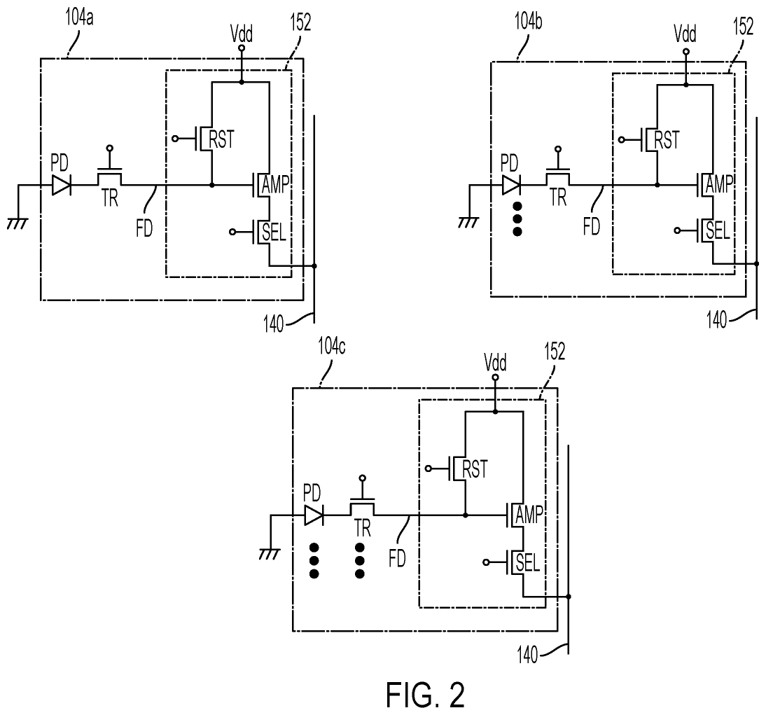

FIG. 2 illustrates different examples of a pixel for inclusion in a light detecting device according to at least one example embodiment. In more detail, FIG. 2 illustrates three example pixels 104a, 104, and 104c. As shown, each pixel 104a to 104c may comprise at least one photoelectric conversion region, such as a photodiode PD formed in a semiconductor substrate. However, a photoelectric conversion region may also be embodied by an organic photoelectric conversion layer sandwiched between upper and lower electrodes or another suitable light detecting structure.

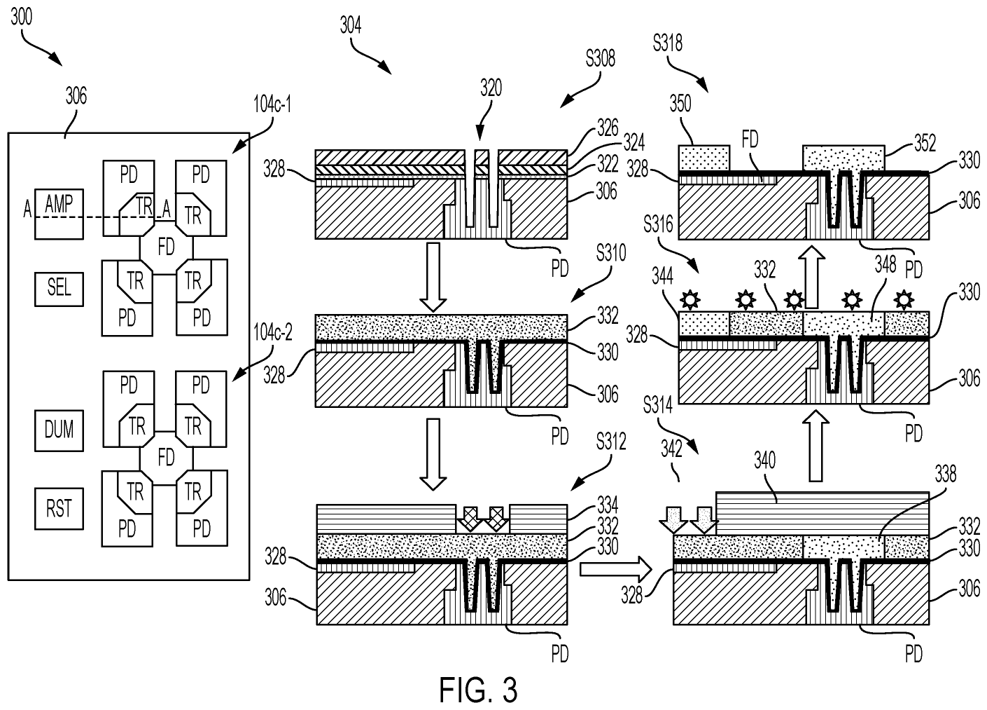

Each pixel 104a to 104c may also comprise or be associated with a plurality of transistors including a transfer transistor TR, a reset transistor RST, an amplification transistor AMP, and a selection transistor SEL. Each pixel 104a to 104c may further include a floating diffusion region FD that stores charge generated by a corresponding PD. The illustrated transistors have functions that are generally well understood in the art. For example, a transfer transistor TR is used to transfer charge from a PD to a floating diffusion region FD, a reset transistor RST is used to reset the floating diffusion region FD in a reset operation based on a voltage Vdd, and an amplification transistor AMP amplifies the charge stored in the floating diffusion region FD to create an electrical signal that is output from the pixel 104 under control of the selection transistor SEL to vertical signal line 140. The RST, AMP, and SEL transistors may be said to form a peripheral circuit 152 and may be laid out at a periphery of a region that includes one or more PDs and one or more TR transistors (see FIG. 3).

In accordance with embodiments of the present disclosure and as discussed in more detail below with reference to the figures, at least one of the plurality of transistors depicted in FIG. 2 comprises a gate having a first conductivity type while remaining ones of the plurality of transistors comprise a gate having a second conductivity type. For example, the gate of each transfer transistor TR in a pixel 104 may comprise a p-type material while gates of the remaining transistors RST, SEL, and AMP comprise a n-type material. Forming the gate of the TR transistor from a p-type material while forming gates of the other transistors from an n-type material may reduce power consumption and/or chip size of the light detecting device, which is a desirable feature in HMDs and other applications.

Still with reference to FIG. 2 and as illustrated with ellipses in pixels 104b and 104c, a pixel 104 may comprise more than one photoelectric conversion region PD and/or more than one transfer transistor TR. Pixel 104b, for example, may comprise two or more PDs that are all connected to a single transfer transistor TR. Although not explicitly shown, pixel 104b may further comprise an additional transistor that enables selection and deselection of some of the additional PDs represented with the ellipsis. For example, in a scenario that requires increased sensitivity, the additional transistor may be turned on so as to allow charge from one or more additional PDs to flow to the TR transistor. If increased sensitivity is not required, then the additional transistor may be turned off so that fewer than all PDs in pixel 104b output charge to the TR transistor.

In some examples and as shown with the ellipses in pixel 104c, a pixel may comprise multiple PDs each with a corresponding TR transistor. For example, a pixel 104c may comprise two, three, or four or more PDs with each PD being connected to a respective transfer transistor TR. Thus, a pixel 104c may be capable of detecting multiple different colors of light, such as if the pixel 104c has a sub-pixel configuration that includes four PDs and four color filters arranged in a suitable pattern, such as a Bayer pattern. FIG. 3 illustrates an example where a pixel 104c has four PDs connected to four different transfer transistors TR. In some examples, a pixel 104c comprises three photoelectric conversion regions that are stacked so as to provide detection of three different colors of light within the same pixel. Such a stack may comprise two inorganic photoelectric conversion regions embodied by PDs formed at different depths within a semiconductor substrate and a third photoelectric conversion region embodied by stack of layers formed on the semiconductor substrate that includes an organic photoelectric conversion layer sandwiched between two electrodes.

Here, it should be appreciated that pixel configurations other than those described and shown are within the scope of the present disclosure. For example, more or fewer transistors may be included in the peripheral circuit 152.

FIG. 3 illustrates an example plan view of a portion of a light detecting device 100 and a method for manufacturing a light detecting device according to at least one example embodiment. In more detail, the plan view at the left side of the figure illustrates a layout 300 including for a light detecting device including a plurality of pixels each of which having a configuration as set forth above for pixel 104a. Meanwhile, the right side of the figure illustrates cross-sectional views taken along line A-A in the plan view to explain a method 304 of manufacturing the light detecting device.

As described herein and depicted in FIGS. 2 and 3, each pixel 104 may include a plurality of transistors, and at least one of the plurality of transistors for a pixel 104 comprises a gate having a first conductivity type while remaining ones of the plurality of transistors comprise a gate having a second conductivity type. The plurality of transistors may include at least one transfer transistor TR, a reset transistor RST, an amplification transistor AMP, and/or a selection transistor SEL. In accordance with embodiments of the present disclosure, the at least one transfer transistor TR comprises the gate having the first conductivity type. Thus, the remaining ones of the plurality of transistors may comprise the amplification transistor AMP, the reset transistor RST, and/or the selection transistor SEL. In accordance with embodiments of the present disclosure, the first conductivity type is p-type and the second conductivity type is n-type.

As shown in FIG. 3, the at least one transfer transistor TR comprises multiple transfer transistors TR each having a gate of the first conductivity type. The illustrated gates may comprise polysilicon (referred to as poly or poly-Si) that is doped with n-type or p-type impurities to form p-poly and n-poly structures. For example, each transfer transistor TR may comprise a gate made of a p-type material, such as p-poly. Meanwhile, the gate of each remaining transistor (RST, AMP, SEL, and/or DUM) may comprise an n-type material, such as n-poly. Forming the gate of transfer transistor TR from a p-type material provides certain advantages over the related, such as removing the need for a negative charge pump circuit which reduces power consumption and chip size while maintaining acceptable dark current performance. Although not explicitly illustrated, drains and sources of transistors AMP, SEL, and RST may comprise doped regions of semiconductor substrate (e.g., substrate 306) arranged at opposing sides of an illustrated gate. As may also be appreciated, a region of a PD adjacent to a gate of a transfer transistor TR may act as one of the source or drain of the transfer transistor TR while the FD may act as the other of the source or drain of the transfer transistor TR.

As also shown in FIGS. 2 and 3, a pixel 104 may include a plurality of photoelectric conversion regions (PD), and each transfer transistor TR transfers charge for one of the plurality of photoelectric conversion regions. In some examples, such as the example shown in FIG. 3, a pixel 104 may further comprise a shared floating diffusion FD coupled to the plurality of photoelectric conversion regions PD.

Here, it should be appreciated that the layout 300 and cross sectional views in FIG. 3 do not necessarily illustrate every element that would exist in practice and instead illustrates elements that are useful for explaining aspects of the present disclosure. Moreover, as should be appreciated from the cross sectional views in the method 304, the elements illustrated in layout 300 are not necessarily formed within the same plane of a pixel and may be formed in different layers of the light detecting device 100. Instead, the layout 300 is intended to show the relative arrangement of gates of transistors, PDs, and FDs which are considered useful for explaining aspects of the present disclosure.

More specifically, the layout 300 in FIG. 3 shows two sets of photoelectric conversion regions PDs and transfer transistors TRs for two pixels 104c-1 and 104c-2 with the illustrated set of illustrated RST, AMP, and SEL transistors and dummy gate DUM belonging to pixel 104c-1. The same set of transistors exists for pixel 104c-2 (e.g., not shown but at a right side of the layout 300) but their illustration is not necessary for explaining aspects of the present disclosure.

Now with reference pixel 104c-1 and the views shown in FIG. 3, the layout 300 illustrates four PDs arranged in a 2×2 matrix. Each PD generates electric charge based on an amount of light incident and transfers the charge to a shared floating diffusion region FD through respective gates of transfer transistors TR. Although not explicitly shown, wirings in one or more wiring layers electrically connect the floating diffusion FD (which may correspond to a doped region of semiconductor substrate 306) to the amplification transistor AMP and the reset transistor RST as shown in FIG. 2 so that the charge stored in the floating diffusion region FD may be amplified or reset depending on the stage of image capture. As shown in the cross sectional views, each PD may be disposed in the semiconductor substrate 306 and formed in accordance with known techniques. For example, each PD may be formed by doping a well region 308 (e.g., a p-well region) with an impurity having an opposite conductivity type (e.g., n-type) to thereby create a pn junction within the semiconductor substrate 306 that enables conversion of light into electric charge.

Layout 300 further illustrates gates of transfer transistors TR that are arranged at or over respective corners of each PD. The gates of the transfer transistors TR in this example are formed to have six sides but the gates may be formed with any suitable number of sides. Meanwhile, gates for the amplification transistor AMP, the selection transistor SEL, and the reset transistor RST are aligned with one another in a vertical direction and located at one side (a periphery) of the pixel 104c-1. Layout 300 further illustrates a dummy gate DUM that is also aligned with gates of the other transistors. The dummy gate DUM may exist for capacitance matching purposes without being used within a stages of image capture. For example, dummy gate DUM does not have a transistor function and exists only for capacitance matching. As illustrated, each gate formed at the periphery of the pixel 104c-1 may have a rectangular shape, but other shapes are possible. Of course, the dummy gate DUM may also be omitted if desired. Notably, the AMP and SEL gates are formed adjacent to pixel 104c-1 while the DUM and RST gates are formed adjacent to a different pixel 104c-2. As alluded to above, pixel 104c-2 may have its own peripheral circuit with AMP, SEL, DUM, and RST gates formed to the right of the illustrated layout 300 with the gates being arranged in the same way as those shown but in reverse order from bottom to top (e.g., with the AMP gate as the bottommost gate arranged to the right of pixel 104c-2 and with the RST gate as the topmost gate arranged to the right of pixel 104c-1).

As described in more detail below with reference to a method 304 of manufacturing a light detecting device, the gate of the transfer transistor TR may comprise a vertical gate that extends into the semiconductor substrate 306 in which one or more PDs are formed. As noted above, the method 304 includes steps illustrated with cross-sectional views taken along line A-A of the layout 300.

The method 304 may comprise a step S308, which includes forming one or more trenches 320 for a vertical gate of a transfer transistor TR. Step S308 specifically shows forming two trenches 320, which be accomplished via a suitable etching technique. The trench or trenches 320 may be formed to a suitable depth within or near the PD and are used to form a dual vertical gate structure as described in more detail below. It should be appreciated that a number of steps may occur prior to step S308. For example, prior to step S308, a photoelectric conversion region PD may be formed within a semiconductor substrate 306, one or more suitable mask layers 322, 324, and 326 may be formed on the semiconductor substrate 306, and one or more doped regions 328 (e.g., n-type regions) may be formed within the semiconductor substrate 306 to be used as the floating diffusion FD and/or as a source or drain of transistors (e.g., TR and/or transistor AMP).

Step S310 includes removing the one or more mask layers 322, 324, and 326 (e.g., by etching), and then depositing a gate insulator film (e.g., silicon dioxide) and a conductive material 332, such as poly-Si, on the insulator film. In more detail, step S310 deposits the gate insulator film 330 into the trenches 320 and onto the surface of the semiconductor substrate 306 before depositing the conductive material 332 onto the insulator film 330. Step S310 may further include a planarization step that planarizes the conductive material 332.

Step S312 includes forming a mask layer 334 on the conductive material 332 and patterning the mask layer 334 to form an opening 336 that exposes the conductive material 332 in a region that corresponds to a gate of the transfer transistor TR. Thereafter, p-type ion implantation is performed through opening 336 to form the p-type conductive material 338 (e.g., p-doped poly-Si).

Step S314 includes forming mask layer 340 on conductive material 332, including on p-doped conductive material 338, and patterning the mask layer 340 to form an opening 342. Thereafter, n-type ion implantation is performed to form n-type conductive material 344 (e.g., n-doped poly-Si).

Step S316 includes removing the mask layer 340 and annealing the conductive material 332 with doped regions 344 and 348.

Step S318 includes patterning (etching) the conductive material 332 to form n-type gate 350 of the amplification transistor AMP and the p-type gate 352 of the transfer transistor TR. As may be appreciated, the p-type gate 352 corresponds to a vertical gate that has a first part that extends into the semiconductor substrate 306 and a second part that extends into the semiconductor substrate 306 and that is spaced apart from the first part. Stated another way, gate 352 may be a two-pronged (or dual) vertical gate of a first conductivity type (e.g., p-type) that extends into the semiconductor substrate 306.

Here, it should be appreciated that while the views in FIG. 3 show steps for forming one transfer transistor TR and the amplification transistor AMP, it should be appreciated that the other transfer transistors TR in FIG. 3 may be formed simultaneously with the illustrated transfer transistor TR and that the remaining transistors RST, AMP, and SEL, and dummy gate DUM in FIG. 3 may be formed simultaneously with the illustrated amplification transistor AMP. In addition, it should be appreciated that gates of transistors RST, AMP, and/or SEL (and dummy gate DUM) may alternatively be formed of p-type material, such as p-poly.

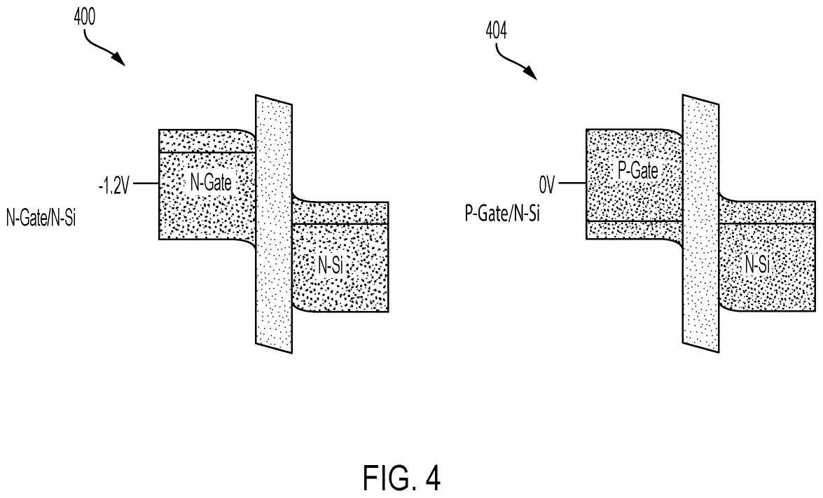

As may be appreciated from the discussion thus far, example embodiments of the present disclosure are directed to light detecting devices that achieve advantages such as reduced power consumption, reduced chip size, and/or reduced unwanted capacitance compared to the related art by forming gates of transfer transistors TR from a p-type material, such as p-type polysilicon (p-poly), while forming the gates of other transistors (RST, AMP, and/or SEL) from n-type material (e.g., n-poly). In addition and as shown in FIG. 4, an n-type gate in n-type silicon and p-type gate in n-type silicon have similar band diagrams 400 and 404, respectively, except that the p-type gate has the more desirable off voltage of 0V to avoid using a negative charge pump circuit. Simulations have further shown that a p-type transfer gate also has a maximum surface potential that is close to a reference condition, meaning that the p-type transfer gate achieves good white spot performance.

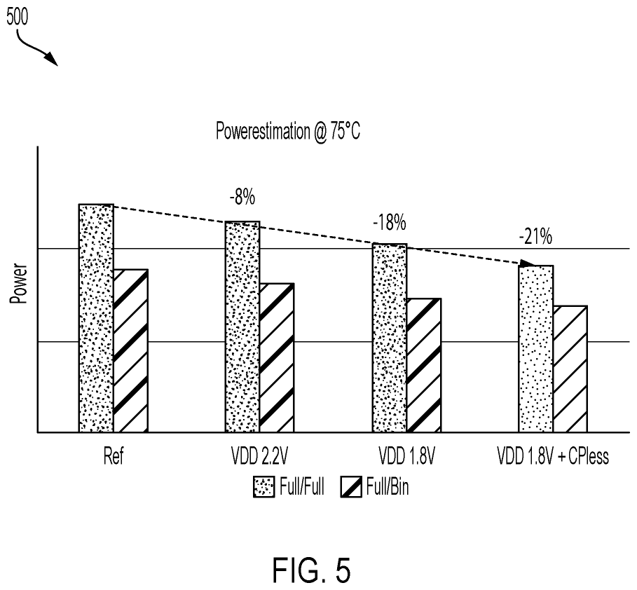

Moreover, as shown by graph 500 in FIG. 5, example embodiments provide the ability to omit the negative charge pump circuit by forming the gate of transistor TR from a p-type material to achieve about a 20% reduction in power consumption compared to a reference device that includes a charge pump circuit to drive a transfer gate formed from n-type material.

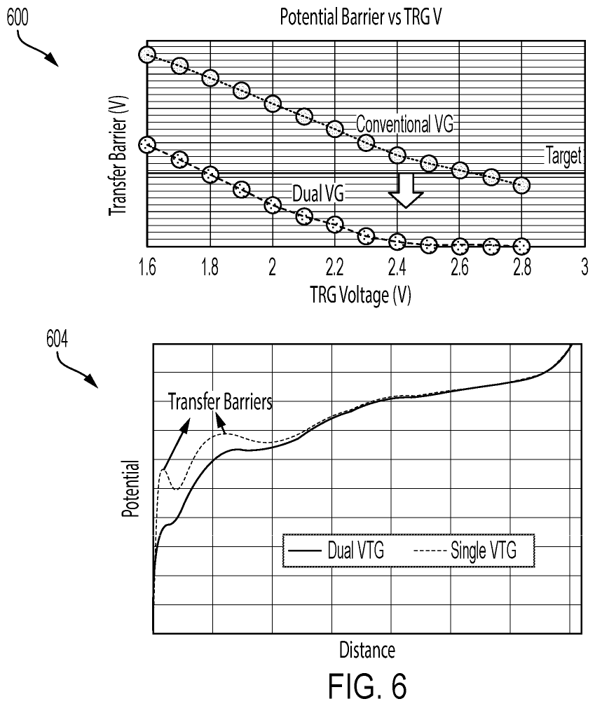

As described above, example embodiments further propose light detecting devices with p-type transfer gates that have a dual vertical transfer gate (DVTG) structure, which improves electron transfer which in turn improves image quality. With reference to FIG. 6 and the graph 600 of transfer barrier vs. on voltage and the potential profiles in graph 604, the DVTG structure requires less voltage to meet a desired transfer barrier target compared to a single VG structure (e.g., about 1.8V compared to about 2.6V), thereby providing reduced power consumption.

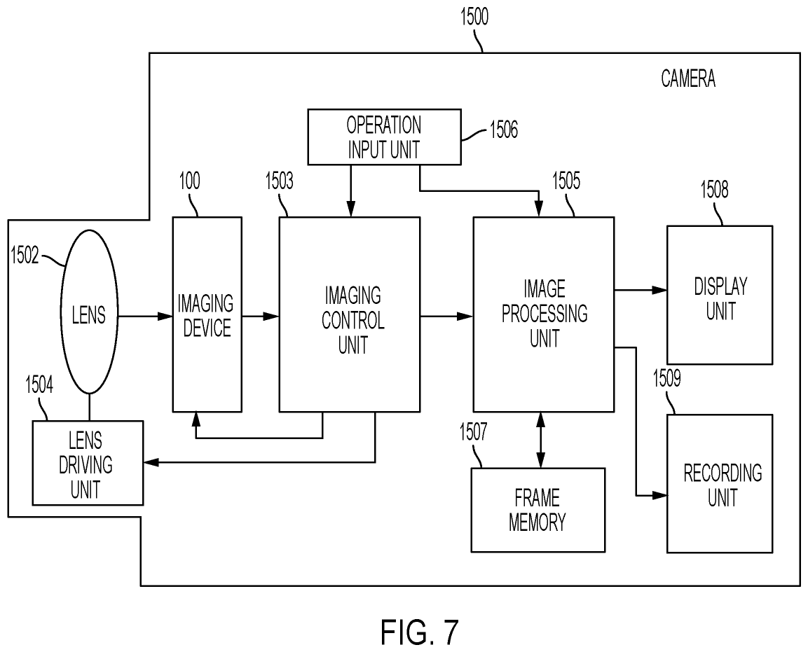

FIG. 7 is a block diagram illustrating a possible configuration of a camera 1500 that is an example of an electronic apparatus to which a light detecting device 100 having pixels 104 in accordance with embodiments of the present disclosure may be applied. As depicted in the figure, the camera 1500 includes an optical system or lens 1502, a light detecting device 100, an imaging control unit 1503, a lens driving unit 1504, an image processing unit 1505, an operation input unit 1506, a frame memory 1507, a display unit 1508, and a recording unit 1509.

The optical system 1502 includes a lens (or lenses) of the camera 1500. The optical system 1502 collects light from within a field of view of the camera 1500, which can encompass a scene containing an object, and focuses the light onto the light detecting device 100. As can be appreciated by one of skill in the art after consideration of the present disclosure, the field of view is determined by various parameters, including a focal length of the lens, the size of the effective area of the light detecting device 100, and the distance of the light detecting device 100 from the lens. In addition to one or more lenses, the optical system 1502 can include other components, such as a variable aperture and a mechanical shutter. The optical system 1502 directs the collected light to the light detecting device 100 to form an image of the object on a light incident surface of the light detecting device 100.

As discussed elsewhere herein, the light detecting device 100 includes a plurality of pixels 104. Moreover, the light detecting device 100 can include a semiconductor element or substrate 306 in which the pixels 104 each include a number of sub-pixels that are formed as photosensitive areas or photodiodes within the substrate 306. In addition, as also described elsewhere herein, each pixel 104 may include a p-type transfer gate. In general, pixels 104 generate analog signals that are proportional to an amount of light incident thereon. These analog signals can be converted into digital signals in a circuit, such as a column signal processing circuit 120, included as part of the light detecting device 100, or in a separate circuit or processor. The digital signals can then be output.

The imaging control unit 1503 controls imaging operations of the light detecting device 100 by generating and outputting control signals to the light detecting device 100. Further, the imaging control unit 1503 can perform autofocus in the camera 1500 on the basis of image signals output from the light detecting device 100. Here, an autofocus system may detect the focus position of the optical system 1502 and automatically adjust the focus position. For example, a method in which an image plane phase difference is detected by phase difference pixels arranged in the light detecting device 100 to detect a focus position (image plane phase difference autofocus) can be used. Further, a method in which a position at which the contrast of an image is highest is detected as a focus position (contrast autofocus) can also be applied. The imaging control unit 1503 adjusts the position of the lens 1001 through the lens driving unit 1504 on the basis of the detected focus position, to thereby perform autofocus. Note that the imaging control unit 1503 and/or other “units” described with reference to FIG. 7 can include, for example, a DSP (Digital Signal Processor) equipped with firmware.

The lens driving unit 1504 drives the optical system 1502 on the basis of control of the imaging control unit 1503. The lens driving unit 1504 can drive the optical system 1502 by changing the position of included lens elements using a built-in motor.

The image processing unit 1505 processes image signals generated by the light detecting device 100. The image processing unit 1505 can include, for example, a microcomputer equipped with firmware, and/or a processor that executes application programming, to implement processes for identifying color information in collected image information as described herein.

The operation input unit 1506 receives operation inputs from a user of the camera 1500. As the operation input unit 1506, for example, a push button or a touch panel can be used. An operation input received by the operation input unit 1506 is transmitted to the imaging control unit 1503 and the image processing unit 1505. After that, processing corresponding to the operation input, for example, the collection and processing of imaging an object or the like, is started.

The frame memory 1507 is a memory configured to store frames that are image signals for one screen or frame of image data. The frame memory 1507 is controlled by the image processing unit 1505 and holds frames in the course of image processing.

The display unit 1508 can display information processed by the image processing unit 1505. For example, a liquid crystal panel can be used as the display unit 1508.

The recording unit 1509 records image data processed by the image processing unit 1505. As the recording unit 1509, for example, a memory card or a hard disk can be used.

An example of a camera 1500 to which embodiments of the present disclosure can be applied has been described above. The light detecting device 100 of the camera 1500 can be configured as described herein.

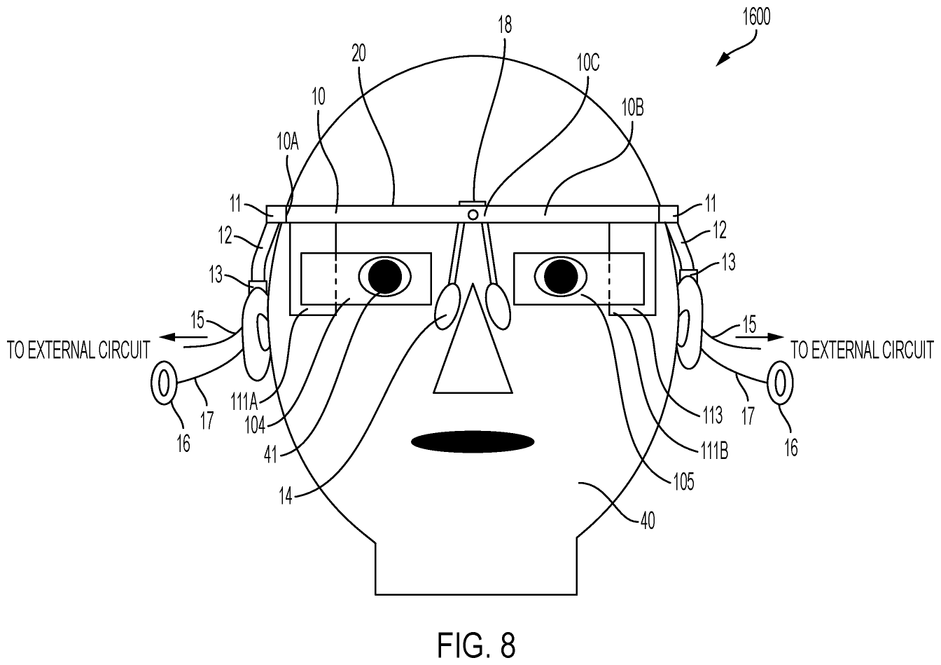

FIG. 8 illustrates a schematic view of a head mounted display (HMD) 1600 according to at least one example embodiment.

The HMD 1600 may include a wearable frame 10 that supports elements of the HMD 1600, hinges 11 at ends 10A of the frame 10 that enable movement of temple portions 12 that hold the HMD 1600 to the head of an observer 40, ear pieces 13 that removably mount to ears of the observer 40, nose pads 14, wiring 15 that connects to an external processing circuit (not shown) where image processing operations are carried out, for example, on the basis of output from camera 18. The HMD 1600 may further include headphones 16, headphone wirings 17, an image sensor or camera 18 mounted to a face 10B of the frame 10 in a central portion 10C of the frame 10, a member 20 to which image generating devices 111A and 111B are mounted through, for example, a casing 113, and waveguides 105 that rest in front of pupils 41 of the observer 40 when wearing the HMD 1600. The camera 18 may be implemented with the same or similar structure as camera 1500 described above and include a light detecting device 100 as described herein. The image generating devices 111A and 111B may each include an optical system for providing input light to a respective waveguide 105. The optical system for each image generating device 111A and 111B may include one or more light sources, one or more lenses, one or more prisms or mirrors, one or more light modulators, and/or other suitable elements for generating input light for a waveguide 105. Each waveguide 105 may receive input light from one of the image generating devices 111A and 111B and output light to the user's eyes.

Here, it should be appreciated that the above described details relate to one non-limiting example of an HMD 1600, and the HMD 1600 may include more or fewer elements than those illustrated and described above.

The embodiments described with reference to FIGS. 1-8 may be combined with one another in any suitable manner.

While this technology has been described in conjunction with a number of embodiments, it is evident that many alternatives, modifications and variations would be or are apparent to those of ordinary skill in the applicable arts. Accordingly, it is intended to embrace all such alternatives, modifications, equivalents, and variations that are within the spirit and scope of this disclosure.

It should be appreciated that inventive concepts cover any embodiment in combination with any one or more other embodiment, any one or more of the features disclosed herein, any one or more of the features as substantially disclosed herein, any one or more of the features as substantially disclosed herein in combination with any one or more other features as substantially disclosed herein, any one of the aspects/features/embodiments in combination with any one or more other aspects/features/embodiments, use of any one or more of the embodiments or features as disclosed herein. It is to be appreciated that any feature described herein can be claimed in combination with any other feature(s) as described herein, regardless of whether the features come from the same described embodiment.

Any processing devices, control units, processing units, etc. discussed above may correspond to one or many computer processing devices, such as a Field Programmable Gate Array (FPGA), an Application-Specific Integrated Circuit (ASIC), any other type of Integrated Circuit (IC) chip, a collection of IC chips, a microcontroller, a collection of microcontrollers, a microprocessor, Central Processing Unit (CPU), a digital signal processor (DSP) or plurality of microprocessors that are configured to execute the instructions sets stored in memory.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device. Program code embodied on a computer readable signal medium may be transmitted using any appropriate medium, including but not limited to wireless, wireline, optical fiber cable, RF, etc., or any suitable combination of the foregoing.

The foregoing discussion has been presented for purposes of illustration and description. The foregoing is not intended to limit the disclosure to the form or forms disclosed herein. In the foregoing Detailed Description for example, various features of the disclosure are grouped together in one or more aspects, embodiments, and/or configurations for the purpose of streamlining the disclosure. The features of the aspects, embodiments, and/or configurations of the disclosure may be combined in alternate aspects, embodiments, and/or configurations other than those discussed above. This method of disclosure is not to be interpreted as reflecting an intention that the claims require more features than are expressly recited in each claim. Rather, as the following claims reflect, inventive aspects lie in less than all features of a single foregoing disclosed aspect, embodiment, and/or configuration. Thus, the following claims are hereby incorporated into this Detailed Description, with each claim standing on its own as an embodiment of the disclosure.

Moreover, though the description has included description of one or more aspects, embodiments, and/or configurations and certain variations and modifications, other variations, combinations, and modifications are within the scope of the disclosure, e.g., as may be within the skill and knowledge of those in the art, after understanding the present disclosure. It is intended to obtain rights which include alternative aspects, embodiments, and/or configurations to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

It should be appreciated that inventive concepts cover any embodiment in combination with any one or more other embodiments, any one or more of the features disclosed herein, any one or more of the features as substantially disclosed herein, any one or more of the features as substantially disclosed herein in combination with any one or more other features as substantially disclosed herein, any one of the aspects/features/embodiments in combination with any one or more other aspects/features/embodiments, use of any one or more of the embodiments or features as disclosed herein. It is to be appreciated that any feature described herein can be claimed in combination with any other feature(s) as described herein, regardless of whether the features come from the same described embodiment.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

Various aspects of the present disclosure are described herein with reference to drawings that may be schematic illustrations of idealized configurations.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure.

As used herein, the singular forms “a,” “an,” and “the” are intended to include the plural forms as well, unless the context clearly indicates otherwise. It will be further understood that the terms “include,” “including,” “includes,” “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

Example embodiments may be configured according to the following:

(1) A light detecting device, comprising:
a photoelectric conversion region that is disposed in a semiconductor substrate and that converts light into electric charge; and
a plurality of transistors coupled to the photoelectric conversion region, wherein at least one transistor of the plurality of transistors comprises a gate having a first conductivity type while remaining ones of the plurality of transistors comprise a gate having a second conductivity type.

(2) The light detecting device of (1), wherein the first conductivity type is p-type and the second conductivity type is n-type.

(3) The light detecting device of one or more of (1) to (2), wherein the plurality of transistors comprise at least one transfer transistor, a reset transistor, an amplification transistor, and a selection transistor.

(4) The light detecting device of one or more of (1) to (3), wherein the at least one transfer transistor comprises the gate having the first conductivity type.

(5) The light detecting device of one or more of (1) to (4), wherein the at least one transfer transistor comprises multiple transfer transistors each having a gate of the first conductivity type.

(6) The light detecting device of one or more of (1) to (5), further comprising:
a plurality of photoelectric conversion regions that includes the photoelectric conversion region, wherein each transfer transistor transfers charge for one of the plurality of photoelectric conversion regions.

(7) The light detecting device of one or more of (1) to (6), further comprising:
a shared floating diffusion coupled to the plurality of photoelectric conversion regions.

(8) The light detecting device of one or more of (1) to (7), wherein the at least one transistor comprises a transfer transistor.

(9) The light detecting device of one or more of (1) to (8), wherein the gate of the transfer transistor is a vertical gate that extends into the semiconductor substrate.

(10) The light detecting device of one or more of (1) to (9), wherein the vertical gate comprises a first part that extends into the semiconductor substrate and a second part that extends into the semiconductor substrate and that is spaced apart from the first part.

(11) The light detecting device of one or more of (1) to (10), wherein the remaining ones of the plurality of transistors comprise an amplification transistor, a reset transistor, and a selection transistor.

(12) The light detecting device of one or more of (1) to (11), wherein the gate of the at least one transistor comprises polysilicon.

(13) An electronic apparatus, comprising:
a signal processing circuit; and
a light detecting device, comprising:
   a photoelectric conversion region that is disposed in a semiconductor substrate and that converts light into electric charge; and
   a plurality of transistors coupled to the photoelectric conversion region, wherein at least one transistor of the plurality of transistors comprises a gate having a first conductivity type while remaining ones of the plurality of transistors comprise a gate having a second conductivity type.

(14) The electronic apparatus of (13), wherein the first conductivity type is p-type and the second conductivity type is n-type.

(15) The electronic apparatus of one or more of (13) to (14), wherein the at least one transistor comprises a transfer transistor.

(16) The electronic apparatus of one or more of (13) to (15), wherein the gate of the transfer transistor is a vertical gate that extends into the semiconductor substrate.

(17) The electronic apparatus of one or more of (13) to (16), wherein the vertical gate comprises a first part that extends into the semiconductor substrate and a second part that extends into the semiconductor substrate and that is spaced apart from the first part.

(18) The electronic apparatus of one or more of (13) to (17), wherein the remaining ones of the plurality of transistors comprise an amplification transistor, a reset transistor, and a selection transistor.

(19) A light detecting device, comprising:
a photoelectric conversion region that is disposed in a semiconductor substrate and that converts light into electric charge; and
a plurality of transistors coupled to the photoelectric conversion region, wherein at least one transistor of the plurality of transistors comprises a two-pronged vertical gate of a first conductivity type that extends into the semiconductor substrate.

(20) The light detecting device of (19), wherein remaining ones of the plurality of transistors have gates of the first conductivity type or of a second conductivity type.

It is claimed that:

1. A light detecting device, comprising:
a photoelectric conversion region that is disposed in a semiconductor substrate and that converts light into electric charge; and
a plurality of transistors coupled to the photoelectric conversion region, wherein at least one transistor of the plurality of transistors comprises a gate having a first conductivity type while remaining ones of the plurality of transistors comprise a gate having a second conductivity type.

2. The light detecting device of claim 1, wherein the first conductivity type is p-type and the second conductivity type is n-type.

3. The light detecting device of claim 1, wherein the plurality of transistors comprise at least one transfer transistor, a reset transistor, an amplification transistor, and a selection transistor.

4. The light detecting device of claim 3, wherein the at least one transfer transistor comprises the gate having the first conductivity type.

5. The light detecting device of claim 4, wherein the at least one transfer transistor comprises multiple transfer transistors each having a gate of the first conductivity type.

6. The light detecting device of claim 5, further comprising:
a plurality of photoelectric conversion regions that includes the photoelectric conversion region, wherein each transfer transistor transfers charge for one of the plurality of photoelectric conversion regions.

7. The light detecting device of claim 6, further comprising:
a shared floating diffusion coupled to the plurality of photoelectric conversion regions.

8. The light detecting device of claim 1, wherein the at least one transistor comprises a transfer transistor.

9. The light detecting device of claim 8, wherein the gate of the transfer transistor is a vertical gate that extends into the semiconductor substrate.

10. The light detecting device of claim 9, wherein the vertical gate comprises a first part that extends into the semiconductor substrate and a second part that extends into the semiconductor substrate and that is spaced apart from the first part.

11. The light detecting device of claim 8, wherein the remaining ones of the plurality of transistors comprise an amplification transistor, a reset transistor, and a selection transistor.

12. The light detecting device of claim 1, wherein the gate of the at least one transistor comprises polysilicon.

13. An electronic apparatus, comprising:
a signal processing circuit; and
a light detecting device, comprising:
a photoelectric conversion region that is disposed in a semiconductor substrate and that converts light into electric charge; and
a plurality of transistors coupled to the photoelectric conversion region, wherein at least one transistor of the plurality of transistors comprises a gate having a first conductivity type while remaining ones of the plurality of transistors comprise a gate having a second conductivity type.

14. The electronic apparatus of claim 13, wherein the first conductivity type is p-type and the second conductivity type is n-type.

15. The electronic apparatus of claim 13, wherein the at least one transistor comprises a transfer transistor.

16. The electronic apparatus of claim 15, wherein the gate of the transfer transistor is a vertical gate that extends into the semiconductor substrate.

17. The electronic apparatus of claim 16, wherein the vertical gate comprises a first part that extends into the semiconductor substrate and a second part that extends into the semiconductor substrate and that is spaced apart from the first part.

18. The electronic apparatus of claim 15, wherein the remaining ones of the plurality of transistors comprise an amplification transistor, a reset transistor, and a selection transistor.

19. A light detecting device, comprising:
a photoelectric conversion region that is disposed in a semiconductor substrate and that converts light into electric charge; and
a plurality of transistors coupled to the photoelectric conversion region, wherein at least one transistor of the plurality of transistors comprises a two-pronged vertical gate of a first conductivity type that extends into the semiconductor substrate.

20. The light detecting device of claim 19, wherein remaining ones of the plurality of transistors have gates of a second conductivity type.
